(19) United States
(12) Patent Application Publication
(10) Pub. No.: US 2017/0012239 A1
(43) Pub. Date: Jan. 12, 2017

(54) LIGHT EMITTING APPARATUS

(71) Applicant: PIONEER OLED LIGHTING DEVICES CORPORATION, Kawasaki-shi (JP)

(72) Inventors: Makoto HOSHINA, Yonezawa-shi (JP); Shinsuke TANAKA, Yonezawa-shi (JP); Hidetaka OHAZAMA, Yonezawa-shi (JP); Shinji NAKAJIMA, Yonezawa-shi (JP)

(21) Appl. No.: 15/113,395

(22) PCT Filed: Jan. 21, 2014
(86) PCT No.: PCT/JP2014/051055

§ 371 Date: Jul. 21, 2016

(51) Int. Cl. H01L 51/52

(52) U.S. Cl. CPC H01L 51/5253; H01L 51/5203

(57) ABSTRACT

A light emitting element (102) is formed on a substrate (100), and includes an organic layer (120). Terminals (112 and 132) are formed on the substrate (100), and are connected to the light emitting element (102). A protective film (140) covers the light emitting element (102) and the terminals (112 and 132). An intermediate layer (150) is provided between the terminal (112) and the protective film (140) and between the terminal (132) and the protective film (140). For example, the glass transition temperature or phase transition temperature of the intermediate layer (150) is lower than the glass transition temperature or phase transition temperature of the protective film (140).

### TECHNICAL FIELD

The present invention relates to a light emitting apparatus.

### BACKGROUND ART

In recent years, there has been progress in the development of light emitting apparatuses using an organic EL element as a light source. In the organic EL element, an organic layer is used as a light emitting layer, and thus a sealing structure is required. Generally, the organic EL element is sealed using a sealing member which is formed of glass, a metal or the like. A terminal which is connected to the organic EL element is disposed outside of this sealing member.

Meanwhile, Patent Document 1 discloses connecting a terminal of a liquid crystal display panel to a terminal of a semiconductor unit through conductive particles. Specifically, the terminal of the semiconductor unit is covered with a thermosetting insulating film. The conductive particles break through this insulating film.

In addition, Patent Document 2 discloses connecting a terminal of a liquid crystal display to an external interconnect through conductive particles. Specifically, the terminal of the liquid crystal display is covered with an inorganic insulating layer. The conductive particles break through this inorganic insulating layer. Meanwhile, examples of a method of forming the inorganic insulating layer include sputtering and CVD.

Meanwhile, Patent Document 3 discloses connecting adjacent solar battery cells to each other using a connecting member. Here, a terminal of the solar battery cell is connected to the connecting member using conductive particles. Specifically, the terminal of the solar battery cell is covered with an insulating layer. The conductive particles break through this insulating layer. Examples of materials of the insulating layer include an organic material such as polyimide or polyamide imide and an inorganic material such as silica or alumina. Examples of methods of forming the insulating layer include coating, thermal spraying, dipping, sputtering, vapor deposition, spraying, and the like.

### RELATED DOCUMENTS

### Patent Documents

[Patent Document 1] Japanese Unexamined Patent Application Publication No. H5(1993)-174890

[Patent Document 2] Japanese Unexamined Patent Application Publication No. 2002-116455

[Patent Document 3] Japanese Unexamined Patent Application Publication No. 2009-302327

### SUMMARY OF THE INVENTION

In recent years, techniques for sealing an organic EL element by forming an insulating film are being studied. When the insulating film is formed, consequently, the insulating film is also formed on a terminal of the organic EL element. For this reason, there is a need to devise a way to connect the terminal to a conducting member such as an external interconnect.

The exemplified problem to be solved by the present invention is to facilitate connection of a terminal to a conducting member such as an external interconnect when forming an insulating film to seal an organic EL element.

According to the invention of claim 1, there is provided a light emitting apparatus including: a substrate; a light emitting element formed on the substrate and including an organic layer; a terminal unit electrically connected to the light emitting element; a protective film that covers the light emitting element and the terminal unit; and an intermediate layer located between the protective film and the terminal unit.

### BRIEF DESCRIPTION OF THE DRAWINGS

The above and other objects, features and advantages will be made clearer from certain preferred embodiment described below, and the following accompanying drawings.

FIG. 1 is a cross-sectional view illustrating a configuration of a light emitting apparatus according to an embodiment.

FIG. 2 is a cross-sectional view illustrating a method of connecting a conductive member to a terminal.

FIG. 3 is a cross-sectional view illustrating a method of connecting the conductive member to the terminal.

FIG. 4 is a plan view illustrating a configuration of a light emitting apparatus according to Example 1.

FIG. 5 is a cross-sectional view taken along line A-A of FIG. 4.

FIG. 6 is a cross-sectional view illustrating a modification example of FIG. 5.

FIG. 7 is a cross-sectional view illustrating a modification example of FIG. 5.

FIG. 8 is a cross-sectional view illustrating a configuration of a light emitting apparatus according to Example 2.

FIG. 9 is a plan view illustrating a configuration of a light emitting apparatus according to Example 3.

### DESCRIPTION OF EMBODIMENTS

Hereinafter, an embodiment of the present invention will be described with reference to the accompanying drawings. In all the drawings, like elements are referenced by like reference numerals and the descriptions thereof will not be repeated.

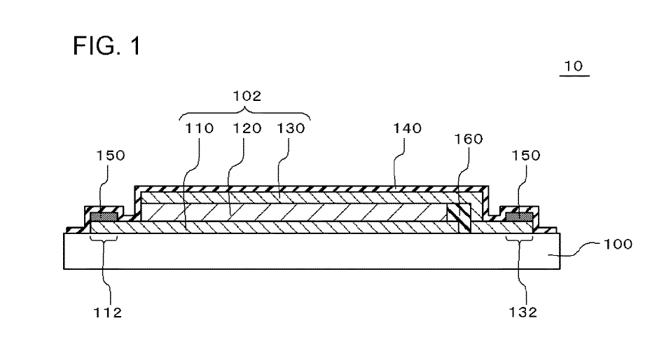

FIG. 1 is a cross-sectional view illustrating a configuration of the light emitting apparatus 10 according to an embodiment. The light emitting apparatus 10 according to the embodiment is, for example, an illumination device or a display, and includes a substrate 100, a light emitting element 102, terminals 112 and 132, a protective film 140, and an intermediate layer 150. The light emitting element 102 is formed on the substrate 100 and includes an organic layer 120. The terminals 112 and 132 are formed on the substrate 100 and are connected to the light emitting element 102. The protective film 140 covers the light emitting element 102 and the terminals 112 and 132. The intermediate layer 150 is provided between the terminal 112 and the protective film 140 and between the terminal 132 and the protective film 140. Hereinafter, a detailed description will be given.

The substrate 100 is a transparent substrate such as, for example, a glass substrate or a resin substrate. The substrate 100 may have flexibility. In this case, the thickness of the substrate 100 is, for example, equal to or greater than 10 μm and equal to or less than 1,000 μm. Even in this case, the substrate 100 may be formed of any of an inorganic material and an organic material. The substrate 100 has a polygonal shape such as, for example, a rectangular shape.

The light emitting element 102 has a configuration in which an organic layer 120 is interposed between a first electrode 110 and a second electrode 130. At least one of the first electrode 110 and the second electrode 130 is configured as a light-transmitting electrode. In addition, the remaining electrode is formed of a metal layer made of a metal selected from a first group consisting of, for example, Al, Mg, Au, Ag, Pt, Sn, Zn, and In, or an alloy of metals selected from this first group. The light-transmitting electrode is a mesh-like electrode using, for example, an inorganic material such as an indium tin oxide (ITO), an indium zinc oxide (IZO), a conductive polymer such as a polythiophene derivative, or a nanowire composed of silver or carbon. For example, in the case of a bottom-emission type light emitting element 102 having a configuration in which the first electrode 110, the organic layer 120, and the second electrode 130 are laminated on the substrate 100 in this order, the first electrode 110 is configured as a light-transmitting electrode, and the second electrode 130 is configured as an electrode of Al or the like which reflects light. In addition, in the case of a top-emission type light emitting element 102 having a configuration in which the first electrode 110, the organic layer 120, and the second electrode 130 are laminated on the substrate 100 in this order, the first electrode 110 is configured as an electrode of Al or the like which reflects light, and the second electrode 130 is configured as a light-transmitting electrode. In addition, using both the electrodes (first electrode 110 and second electrode 130) as light-transmitting electrodes, a light-transmitting type light emitting apparatus may be configured (dual-emission type).

The organic layer 120 has a configuration in which, for example, a hole transport layer, a light emitting layer, and an electron transport layer are laminated in this order. A hole injection layer may be formed between the hole transport layer and the first electrode 110. In addition, an electron injection layer may be formed between the electron transport layer and the second electrode 130. The organic layer 120 may be formed by coating, and may be formed by vapor deposition. A portion of the layer may be formed by coating, and the remainder may be formed by vapor deposition. Meanwhile, the organic layer 120 may be formed by vapor deposition using a vapor deposition material, and may be formed by ink jetting, printing, or spraying using a coating material.

The terminals 112 and 132 are formed on a surface of the substrate 100 which has the light emitting element 102 formed thereon. The terminal 112 is connected to the first electrode 110, and the terminal 132 is connected to the second electrode 130. Specifically, a portion of the first electrode 110 without the organic layer 120 formed thereon serves as the terminal 112. In addition, the terminal 132 has the same layer as that of the first electrode 110. Meanwhile, an insulating layer 160 is formed on the substrate 100. The insulating layer 160 insulates and partitions the light emitting element 102. The insulating layer 160 is formed prior to forming the organic layer 120 and the second electrode 130. The insulating layer 160 is formed of a material such as polyimide, a silicon oxide, or a silicon nitride.

Meanwhile, a layer of a material having a lower resistance than that of the first electrode 110 (for example, a metal layer) may be formed on a portion of the first electrode 110 which serves as the terminal 112.

The protective film 140 is formed by film formation, for example, by atomic layer deposition (ALD) or CVD. When the protective film is formed by ALD, the protective film 140 is formed of a film of a metal oxide such as, for example, an aluminum oxide, and the film thickness is, for example, equal to or greater than 10 nm and equal to or less than 200 nm, preferably, equal to or greater than 50 nm and equal to or less than 100 nm. When formed by CVD, the protective film 140 is formed of an inorganic insulating film such as a silicon oxide film, and the film thickness is, for example, equal to or greater than 0.1 μm and equal to less than 10 μm. By providing the protective film 140, the light emitting element 102 is protected from moisture or the like. The protective film 140 may be formed by sputtering. In this case, the protective film 140 is formed of an insulating film such as SiO₂ or SiN. In that case, the film thickness is equal to or greater than 10 nm and equal to or less than 1,000 nm.

The intermediate layer 150 is formed on the terminals 112 and 132. The glass transition temperature or phase transition temperature (for example, melting point) of the intermediate layer 150 is lower than the glass transition temperature or phase transition temperature (for example, melting point) of the protective film 140. The intermediate layer 150 is formed of, for example, the same material as that of at least one layer constituting an organic layer, specifically, the organic layer 120. The material is, for example, the same material as that of the electron transport layer. Meanwhile, it is preferable that the linear expansion coefficient of a material constituting the intermediate layer 150 is larger than the linear expansion coefficient of a material constituting the protective film 140. The thickness of the intermediate layer 150 is, for example, equal to or greater than 5 nm and equal to or less than 200 nm.

In the example shown in FIG. 1, no other layers are present between the terminals 112 and 132 and the intermediate layer 150, and neither are other layers present between the intermediate layer 150 and the protective film 140. However, other layers may present between the terminals 112 and 132 and the intermediate layer 150, and other layers may be present between the intermediate layer 150 and the protective film 140.

Next, a method of manufacturing the light emitting apparatus 10 will be described. First, the first electrode 110 and the terminals 112 and 132 are formed on the substrate 100. The first electrode 110 and the terminals 112 and 132 are formed by, for example, sputtering. Next, the insulating layer 160 is formed between the first electrode 110 and the terminal 132. Then, the organic layer 120 is formed on the first electrode 110. In addition, the intermediate layer 150 is formed on the terminals 112 and 132. In a case where the intermediate layer 150 is formed of the same material as that of a layer constituting the organic layer 120, the intermediate layer 150 is formed in the same process as that for forming the organic layer 120.

Next, the second electrode 130 is formed, and the protective film 140 is further formed. The second electrode 130 is formed by, for example, sputtering, and the protective film 140 is formed by, for example, ALD or CVD.

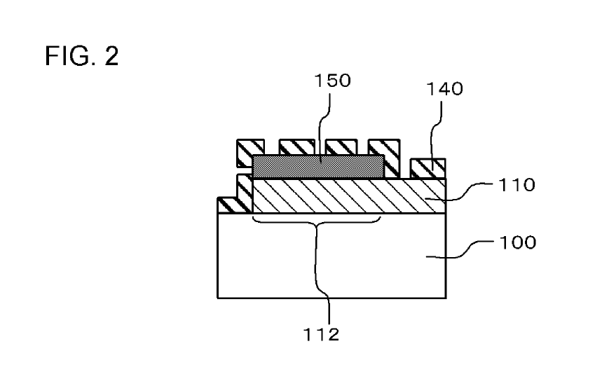

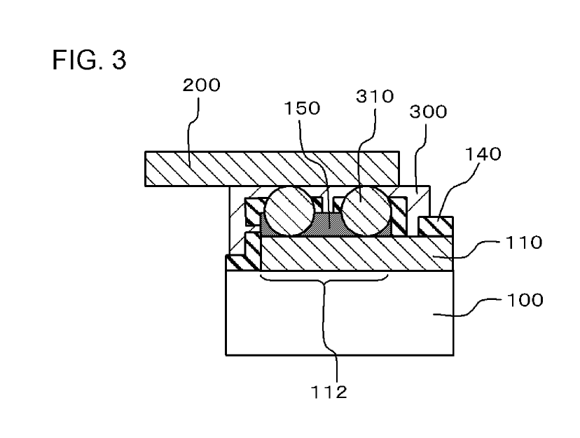

FIGS. 2 and 3 are cross-sectional views illustrating a method of connecting a conductive member 200 to the terminal 112. The conductive member 200 is, for example, a member which is formed of a lead frame, and connects the light emitting apparatus 10 to an interconnect substrate. This interconnect substrate may have, for example, at least a portion of a control circuit of the light emitting apparatus 10 formed therein, and may be without the control circuit formed therein.

First, the lamination portion of the intermediate layer 150 and the protective film 140 is heated and then cooled. At this time, it is preferable that the temperature of the lamination portion is set to be equal to or higher than the glass transition temperature (or equal to or higher than the phase transition temperature such as the melting point) of the protective film 140. This results in a further increase in the amount of expansion of the intermediate layer 150 with respect to the amount of expansion of the protective film 140, causing the selective generation of cracks in the protective film 140 as shown in FIG. 2. Meanwhile, in a case where the glass transition temperature of the intermediate layer 150 is set to 150° C., it is also possible to obtain the same effect in a manufacturing method in which the protective film 140 is formed at a film formation temperature of 150° C. or higher.

Thereafter, as shown in FIG. 3, the conductive member 200 and the terminal 112 are connected to each other using, for example, a conductive adhesive layer 300. In a case where the conductive adhesive layer 300 is used, a conducting member 310 (for example, conductive particles) included in the conductive adhesive layer 300 breaks through the protective film 140 and the intermediate layer 150, and the terminal 112 and the conductive member 200 are connected to each other. Here, since cracks are generated in the protective film 140, the conducting member 310 can easily break through the protective film 140.

As described above, according to the present embodiment, the light emitting element 102 is sealed by the protective film 140. Since the protective film 140 is formed by film formation, the terminals 112 and 132 of the light emitting element 102 are also covered with the protective film 140. Here, the intermediate layer 150 is formed between the terminals 112 and 132 and the protective film 140. For this reason, there is a tendency for cracks to be generated in portions of the protective film 140 which are located on the intermediate layer 150. When cracks are generated in the protective film 140, the conducting member 310 is able to easily break through the protective film 140. Therefore, the conductive member 200 and the first electrode 110 can be easily connected to each other using the conductive adhesive layer 300.

### EXAMPLES

### Example 1

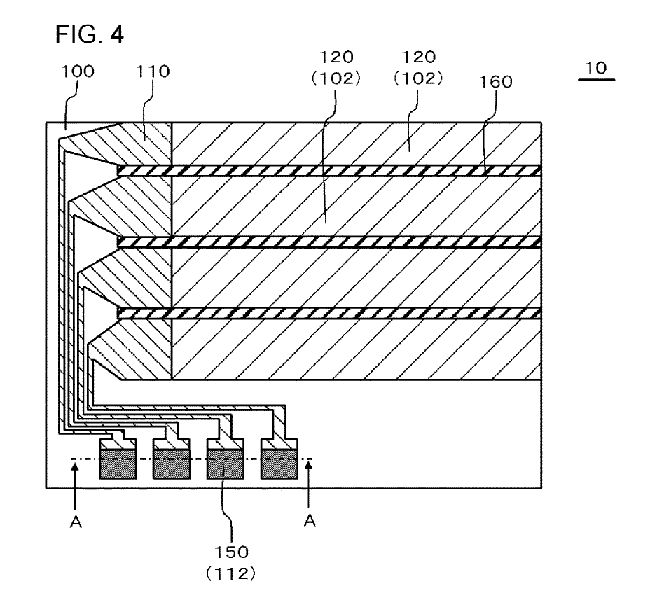

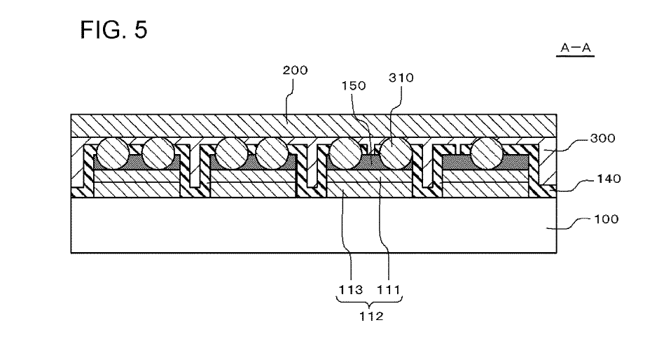

FIG. 4 is a plan view illustrating a configuration of a light emitting apparatus 10 according to Example 1. FIG. 5 is a cross-sectional view taken along line A-A of FIG. 4. Meanwhile, in FIG. 4, the second electrode 130, the protective film 140, the conductive member 200, the conductive adhesive layer 300, the conducting member 310, and the terminal 132 are not shown for the purpose of description.

In the present example, the light emitting apparatus 10 includes a plurality of light emitting elements 102. The insulating layer 160 is formed between adjacent light emitting elements 102. A terminal 112 is formed with respect to each of the plurality of light emitting elements 102. The plurality of terminals 112 are aligned with each other and are disposed on the edge of the substrate 100. The intermediate layer 150 is formed on each of the plurality of terminals 112. As shown in FIG. 5, the conductive adhesive layer 300 is formed across the plurality of terminals 112.

In addition, the terminal 112 has a configuration in which a layer 111 formed of the same material as that of the first electrode 110, and a layer 113 formed of a material (for example, metal) having a lower resistance than that of the layer 111 are laminated in this order. The layer 113 is, for example, a film having Mo, Al, and Mo laminated in this order.

Similarly, a method of connecting the conductive member 200 to the terminal 132 is as described with reference to FIGS. 2 and 3.

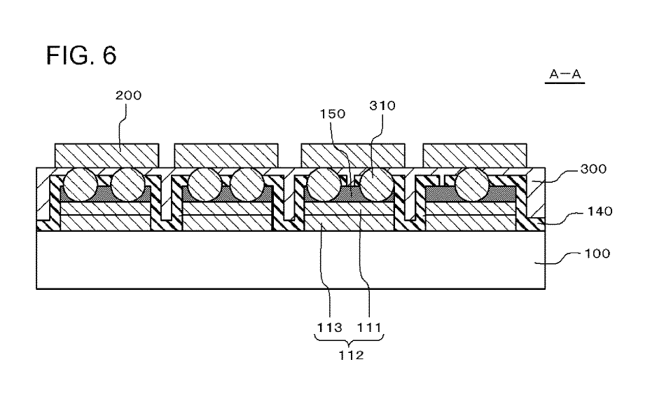

In the example shown in FIG. 5, one conductive member 200 is connected to the plurality of terminals 112. However, as shown in FIG. 6, the plurality of terminals 112 maybe connected to conductive members 200 different from each other.

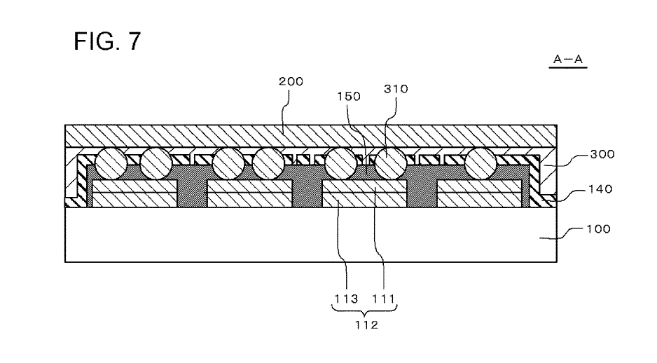

In addition, as shown in FIG. 7, the intermediate layer 150 may be formed across the plurality of terminals 112.

Also in the present example, the intermediate layer 150 is formed between the terminals 112 and 132 and the protective film 140. For this reason, there is a tendency for cracks to be generated in portions of the protective film 140 which are located on the intermediate layer 150. For this reason, the conductive member 310 can easily break through the protective film 140. Therefore, the conducting member 200 can more easily be connected to the first electrode 110 by using the conductive adhesive layer 300.

### Example 2

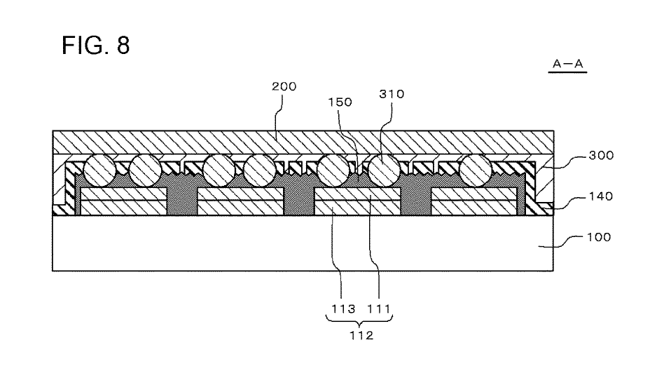

FIG. 8 is a cross-sectional view illustrating a configuration of a light emitting apparatus 10 according to Example 2, and corresponds to FIG. 7 in Example 1. The light emitting apparatus 10 according to the present example has the same configuration as that of the light emitting apparatus 10 according to Example 1, except that irregularities, or concavities and convexities, are formed on the surface of the intermediate layer 150.

The irregularities of the intermediate layer 150 are formed, for example, by partially increasing the thickness of a material forming the intermediate layer 150 during vapor deposition. Such a method of forming the irregularities can also be performed by vapor deposition using a mask. A difference in height between a vertex and a bottom of the irregularities is, for example, equal to or greater than 10 nm and equal to or less than 200 nm. An electron transport layer which is one layer of the organic layer 120 is coated differently using a mask between a region to be the light emitting element 102 and the terminal 112. In addition, the irregularities of the intermediate layer 150 may be formed by printing, etching, or the like.

The protective film 140 is formed on the irregularities of the intermediate layer 150. For this reason, when the intermediate layer 150 and the protective film 140 are heated and cooled, there is a tendency for cracks to be generated in the protective film 140. Therefore, the conducting member 310 can easily break through the protective film 140.

### Example 3

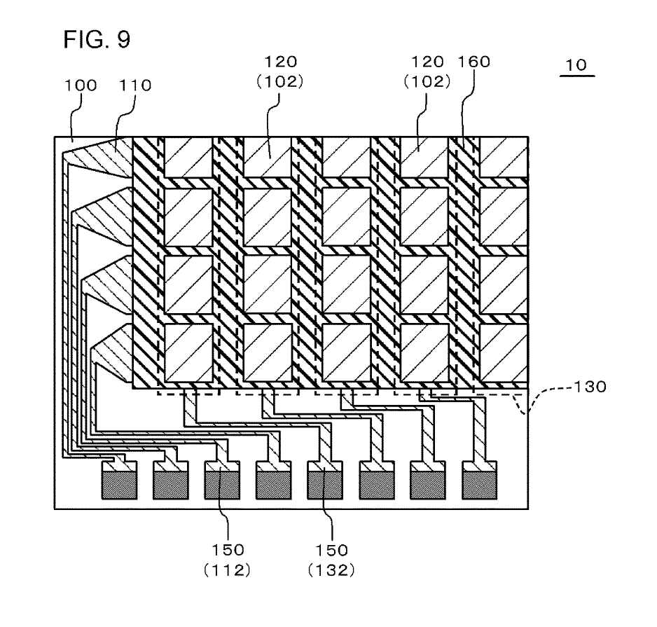

FIG. 9 is a plan view illustrating a configuration of a light emitting apparatus 10 according to Example 3, and corresponds to FIG. 4 in Example 1. In the present example, the light emitting apparatus 10 is a display, and includes a plurality of light emitting elements 102 disposed in a matrix.

Specifically, a plurality of first electrodes 110 extend in parallel to each other, and a plurality of second electrodes 130 extend in parallel to each other and in a direction intersecting (for example, direction orthogonal to) the first electrode 110. The light emitting element 102 is formed at each of the points of intersection between the first electrodes 110 and the second electrodes 130. Specifically, the insulating layer 160 is formed over the plurality of first electrodes 110. An opening is formed in a portion of the insulating layer 160 which is located at the point of intersection between the first electrode 110 and the second electrode 130. The organic layer 120 is provided within this opening.

The terminal 112 is provided to each of the plurality of first electrodes 110, and the terminal 132 is provided to each of the plurality of second electrodes 130. The plurality of terminals 112 and 132 are all disposed along the edge of the substrate 100. In the example shown in this drawing, the plurality of terminals 112 and 132 are all disposed along the same side of the substrate 100. However, the terminal 112 and the terminal 132 maybe disposed along the sides of the substrate 100 which are different from each other.

The intermediate layer 150 is disposed on the plurality of terminals 112 and 132. In the example shown in this drawing, the arrangement of the intermediate layer 150 is the same as that in the example shown in FIG. 5. However, the arrangement of the intermediate layer 150 may be the same as that in the example shown in FIG. 7.

Other configurations are the same as those in Example 1.

Also in the present example, the intermediate layer 150 is formed between the terminals 112 and 132 and the protective film 140. Therefore, the conductive member 200 maybe easily connected to the first electrode 110 using the conductive adhesive layer 300.

As described above, although the embodiment and examples have been set forth with reference to the accompanying drawings, they are merely illustrative of the present invention, and various configurations other than those stated above can be adopted.

1. A light emitting apparatus comprising:
a substrate;
alight emitting element formed on the substrate and including an organic layer;
a terminal unit electrically connected to the light emitting element;
a protective film that covers the light emitting element and the terminal unit; and
an intermediate layer located between the protective film and the terminal unit.

2. The light emitting apparatus according to claim 1, further comprising:
a conductive member located over the protective film and overlapping the terminal unit; and
a conducting member breaking through the protective film and the intermediate layer and connecting the terminal unit to the conductive member.

3. The light emitting apparatus according to claim 2, wherein the glass transition temperature or phase transition temperature of the intermediate layer is lower than the glass transition temperature or phase transition temperature of the protective film.

4. The light emitting apparatus according to claim 3, wherein the conducting member includes a conductive member that penetrates into the protective film and the intermediate layer.

5. The light emitting apparatus according to claim 4, wherein irregularities are formed on a surface of a region of the intermediate layer which overlaps the terminal unit.

6. The light emitting apparatus according to claim 5, wherein the protective film is a metal oxide film.

7. The light emitting apparatus according to claim 6, wherein the intermediate layer is formed of the same material as that of a layer of a portion of the organic layer.
